(19) United States
(12) Patent Application Publication
(10) Pub. No.: US 2024/0047554 A1
(43) Pub. Date: Feb. 8, 2024

(54) SEMICONDUCTOR DEVICE AND MANUFACTURING METHOD THEREOF

(71) Applicant: UNITED MICROELECTRONICS CORP., Hsin-Chu City (TW)

(72) Inventors: Zhi-Cheng Lee, Tainan City (TW); Huai-Tzu Chiang, Tainan City (TW); Chuang-Han Hsieh, Tainan City (TW); Kai-Lin Lee, Kinmen County (TW)

(73) Assignee: UNITED MICROELECTRONICS CORP., Hsin-Chu City (TW)

(21) Appl. No.: 17/899,604

(22) Filed: Aug. 30, 2022

(30) Foreign Application Priority Data
Aug. 3, 2022 (TW) 111129169

(51) Int. Cl. H01L 29/66; H01L 29/778; H01L 23/31

(52) U.S. Cl. CPC H01L 29/66462; H01L 29/778; H01L 23/3171; H01L 23/3192; H01L 29/2003

(57) ABSTRACT

A manufacturing method of a semiconductor device includes the following steps. A III-V compound barrier layer is formed on a III-V compound semiconductor layer. A protection layer is formed on the III-V compound barrier layer. An opening is formed penetrating through the protection layer in a vertical direction and exposing a part of the III-V compound barrier layer. A p-type doped III-V compound material is formed in the opening. A patterned barrier layer is formed on the p-type doped III-V compound material. A contact area between the patterned barrier layer and the p-type doped III-V compound material is less than an area of a top surface of the p-type doped III-V compound material.

### BACKGROUND OF THE INVENTION

### 1. Field of the Invention

The present invention relates to a semiconductor device and a manufacturing method thereof, and more particularly, to a semiconductor device including a III-V compound semiconductor layer and a manufacturing method thereof.

### 2. Description of the Prior Art

Because of the semiconductor characteristics, III-V semiconductor compounds may be applied in many kinds of integrated circuit devices, such as high power field effect transistors, high frequency transistors, or high electron mobility transistors (HEMTs). In the high electron mobility transistor, two semiconductor materials with different band-gaps are combined and heterojunction is formed at the junction between the semiconductor materials as a channel for carriers. In recent years, gallium nitride (GaN) based materials have been applied in the high power and high frequency products because of the properties of wider band-gap and high saturation velocity. Two-dimensional electron gas (2DEG) may be generated by the piezoelectricity property of the GaN-based materials, and the switching velocity may be enhanced because of the higher electron velocity and the higher electron density of the 2DEG. Therefore, how to further improve the electrical performance of transistors formed with III-V compound materials by modifying materials, structures and/or manufacturing methods has become a research direction for people in the related fields.

### SUMMARY OF THE INVENTION

A semiconductor device and a manufacturing method thereof are provided in the present invention. A p-type doped III-V compound material is formed in an opening penetrating through a protection layer for reducing negative influence of related manufacturing processes of forming the p-type doped III-V and/or other subsequent manufacturing processes on other material layers. For example, the amount of dopants diffused from the p-type doped III-V compound material into the III-V compound barrier layer and/or the III-V compound semiconductor layer may be reduced by covering most of the III-V compound barrier layer with the protection layer. Additionally, the damage to the III-V compound barrier layer and/or the III-V compound semiconductor layer in other related manufacturing processes (such as an etching process, but not limited thereto) may be reduced accordingly. Therefore, the purposes of increasing the concentration of two-dimensional electron gas (2DEG), enhancing the drain current (Ids) of the semiconductor device, and/or lowering the leakage current of the semiconductor device may be achieved.

According to an embodiment of the present invention, a manufacturing method of a semiconductor device is provided. The manufacturing method includes the following steps. A III-V compound barrier layer is formed on a III-V compound semiconductor layer. A protection layer is formed on the III-V compound barrier layer. An opening is formed penetrating through the protection layer in a vertical direction and exposes a part of the III-V compound barrier layer. A p-type doped III-V compound material is formed in the opening. A patterned barrier layer is formed on the p-type doped III-V compound material. A contact area between the patterned barrier layer and the p-type doped III-V compound material is less than an area of a top surface of the p-type doped III-V compound material.

According to an embodiment of the present invention, a semiconductor device is provided. The semiconductor device includes a III-V compound semiconductor layer, a III-V compound barrier layer, a protection layer, an opening, a p-type doped III-V compound material, and a patterned barrier layer. The III-V compound barrier layer is disposed on the III-V compound semiconductor layer. The protection layer is disposed on the III-V compound barrier layer. The opening penetrates through the protection layer in a vertical direction. The p-type doped III-V compound material is disposed in the opening. The patterned barrier layer is disposed on the p-type doped III-V compound material. A contact area between the patterned barrier layer and the p-type doped III-V compound material is less than an area of a top surface of the p-type doped III-V compound material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 are schematic drawings illustrating a manufacturing method of a semiconductor device according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 8 is a schematic drawing in a step subsequent to FIG. 7.

FIG. 9 and FIG. 10 are schematic drawings illustrating a manufacturing method of a semiconductor device according to a second embodiment of the present invention, wherein FIG. 10 is a schematic drawing in a step subsequent to FIG. 9.

FIG. 11 and FIG. 12 are schematic drawings illustrating a manufacturing method of a semiconductor device according to a third embodiment of the present invention, wherein FIG. 12 is a schematic drawing in a step subsequent to FIG. 11.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

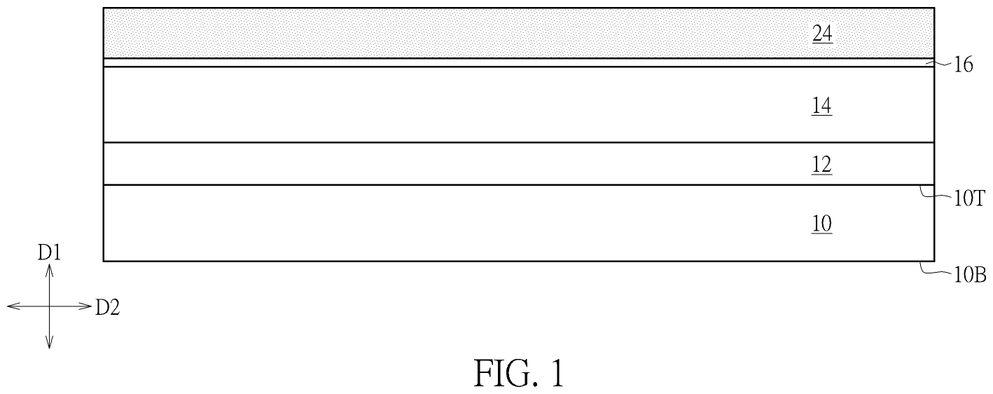

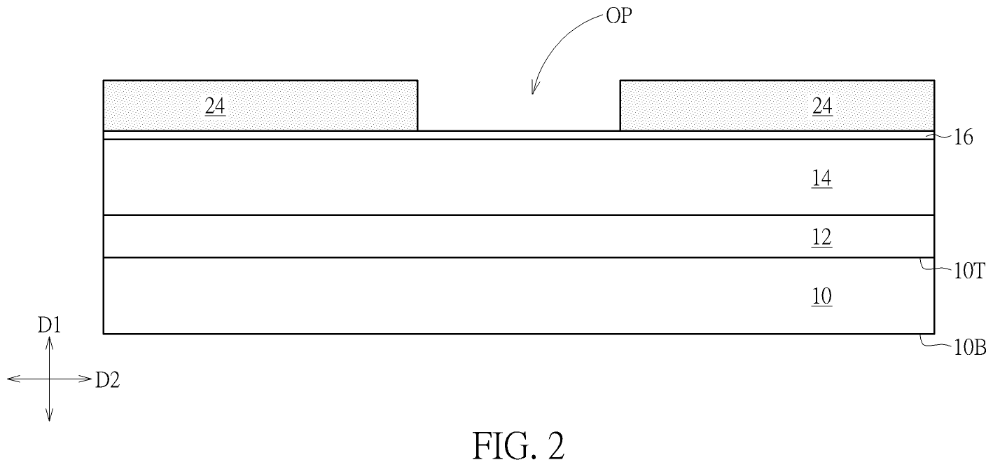

Please refer to FIGS. 1-8. FIGS. 1-8 are schematic drawings illustrating a manufacturing method of a semiconductor device according to a first embodiment of the present invention. The manufacturing method of the semiconductor device in this embodiment includes the following steps. As shown in FIG. 1, a III-V compound barrier layer 16 is formed on a III-V compound semiconductor layer 14, and a protection layer 24 is formed on the III-V compound barrier layer 16. As shown in FIG. 2, an opening OP is formed, and the opening OP penetrates through the protection layer 24 in a vertical direction (such as a direction D1 illustrate in FIG. 2) and exposes a part of the III-V compound barrier layer 16.

Specifically, the manufacturing method in this embodiment may include but is not limited to the following steps. In some embodiments, the III-V compound semiconductor layer 14 described above may be formed on a substrate 10. The substrate 10 may have a top surface 10T and a bottom surface 10B opposite to the top surface 10T in the direction D1, and III-V compound semiconductor layer 14, the III-V compound barrier layer 16, and the protection layer 24 may be formed at a side of the top surface 10T. In addition, the substrate 10 may include a silicon substrate, a silicon carbide (SiC) substrate, a gallium nitride (GaN) substrate, a sapphire substrate, or a substrate made of other suitable materials. In some embodiments, a buffer layer 12 may be formed on the substrate 10 before the step of forming the III-V compound semiconductor layer 14, and the buffer layer 12 may be located between the substrate 10 and the III-V compound semiconductor layer 14 in the direction D1. The buffer layer 12 may include gallium nitride, aluminum gallium nitride (AlGaN), aluminum indium nitride (AlInN), or other suitable buffer materials.

In some embodiments, the direction D1 described above may be regarded as a thickness direction of the substrate 10, and a horizontal direction substantially orthogonal to the direction D1 (such as a direction D2 and other directions orthogonal to the direction D1) may be substantially parallel with the top surface 10T and/or the bottom surface 10B of the substrate 10, but not limited thereto. In this description, a distance between the bottom surface 10B of the substrate 10 and a relatively higher location and/or a relatively higher part in the vertical direction (such as the direction D1) may be greater than a distance between the bottom surface 10B of the substrate 10 and a relatively lower location and/or a relatively lower part in the direction D1. The bottom or a lower portion of each component may be closer to the bottom surface 10B of the substrate 10 in the direction D1 than the top or upper portion of this component. Another component disposed above a specific component may be regarded as being relatively far from the bottom surface 10B of the substrate 10 in the direction D1, and another component disposed under a specific component may be regarded as being relatively close to the bottom surface 10B of the substrate 10 in the direction D1.

In some embodiments, the III-V compound semiconductor layer 14 may include gallium nitride, indium gallium nitride (InGaN), or other suitable III-V compound semiconductor materials. The III-V compound barrier layer 16 may include aluminum gallium nitride, aluminum indium nitride, aluminum gallium indium nitride (AlGaInN), aluminum nitride (AlN), or other suitable III-V compound materials. The protection layer 24 may include oxide dielectric material (such as silicon oxide), nitride dielectric material (such as silicon nitride), or other suitable dielectric materials or insulation materials. As shown in FIG. 2, the opening OP penetrating through the protection layer 24 may be formed by a photolithography process or other suitable approaches, and relatively speaking, most of the III-V compound barrier layer 16 may be covered by the protection layer 24 for reducing the negative influence of the related processes for forming the opening OP on the III-V compound barrier layer 16 and/or the III-V compound semiconductor layer 14.

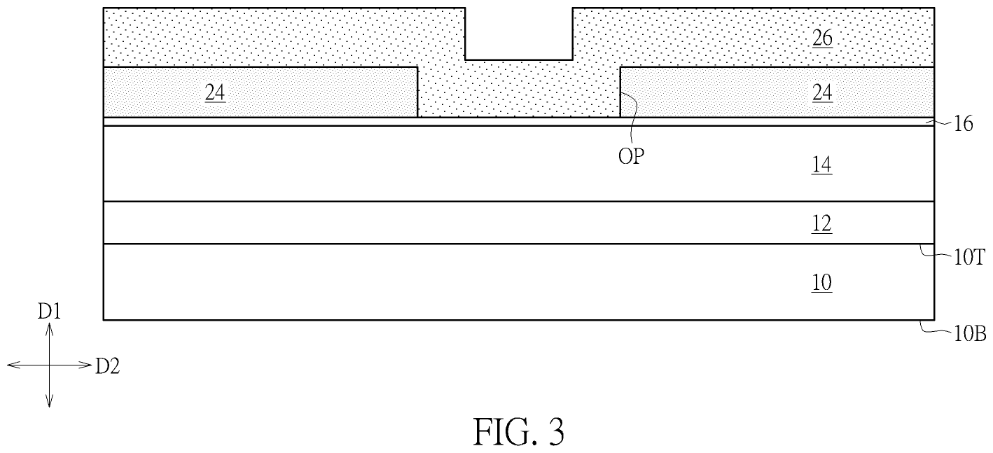

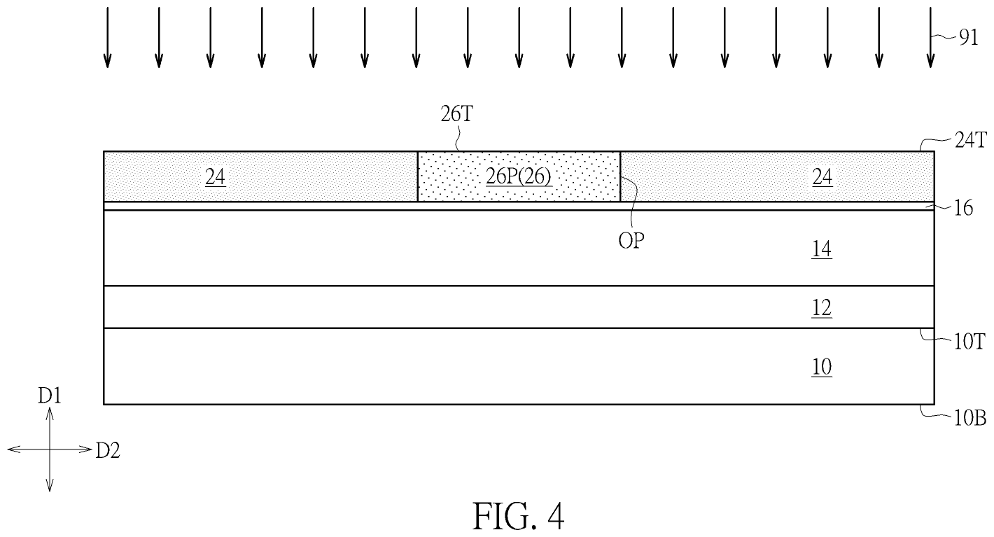

As shown in FIG. 3 and FIG. 4, a p-type doped III-V compound material 26P is formed in the opening OP. In some embodiments, a method of forming the p-type doped III-V compound material 26P may include but is not limited to the following steps. A p-type doped III-V compound layer 26 is formed on the protection layer 24 and the III-V compound barrier layer 16 exposed via the opening OP. A portion of the p-type doped III-V compound layer 26 is formed in the opening OP, and another portion of the p-type doped III-V compound layer 26 is formed outside the opening OP and formed on the protection layer 24. In some embodiments, the opening OP may be fully filled with the p-type doped III-V compound layer 26, but not limited thereto. The p-type doped III-V compound layer 26 may include p-type doped aluminum gallium nitride, p-type doped gallium nitride, or other suitable p-type doped III-V compound materials, and the p-type dopant in the p-type doped III-V compound layer 26 may include magnesium, beryllium (Be), zinc (Zn), cyclopentadienyl magnesium (Cp₂Mg), a combination of the materials described above, or other suitable p-type dopants.

Subsequently, a planarization process 91 may be performed to the p-type doped III-V compound layer 26 for removing the p-type doped III-V compound layer 26 formed outside the opening OP, and the p-type doped III-V compound layer 26 remains in the opening OP after the planarization process 91 may become the p-type doped III-V compound material 26P described above. The planarization process 91 may include a chemical mechanical polishing (CMP) process, an etching back process, or other suitable planarization approaches. Additionally, after the planarization process 91, a top surface 26T of the p-type doped III-V compound material 26P and a top surface 24T of the protection layer 24 may be substantially coplanar, but not limited thereto. It is worth noting that most of the III-V compound barrier layer 16 may be covered by the protection layer 24 without directly contacting the p-type doped III-V compound layer 26 during the formation of the p-type doped III-V compound layer 26, and the negative influence on the III-V compound barrier layer 16 and/or the III-V compound semiconductor layer 14, which is induced from the p-type doped III-V compound layer 26 and/or the related processes for forming the p-type doped III-V compound layer 26, may be reduced accordingly. For example, the amount of the p-type dopants diffused from the p-type doped III-V compound layer 26 into the III-V compound barrier layer 16 and/or the III-V compound semiconductor layer 14 may be reduced by covering most of the III-V compound barrier layer 16 with the protection layer 24, and the electrical performance of the semiconductor device may be improved accordingly. For instance, the concentration of two-dimensional electron gas (2DEG) in the III-V compound semiconductor layer 14 may be increased for enhancing the drain current (Ids) of the semiconductor device, but not limited thereto. In addition, the damage to other material layers (such as the III-V compound barrier layer 16 and/or the III-V compound semiconductor layer 14) in the related processes for forming the p-type doped III-V compound material 26P and/or other subsequent processes may be reduced by forming the protection layer 24, and the manufacturing yield and/or the operation performance of the semiconductor device may be improved accordingly.

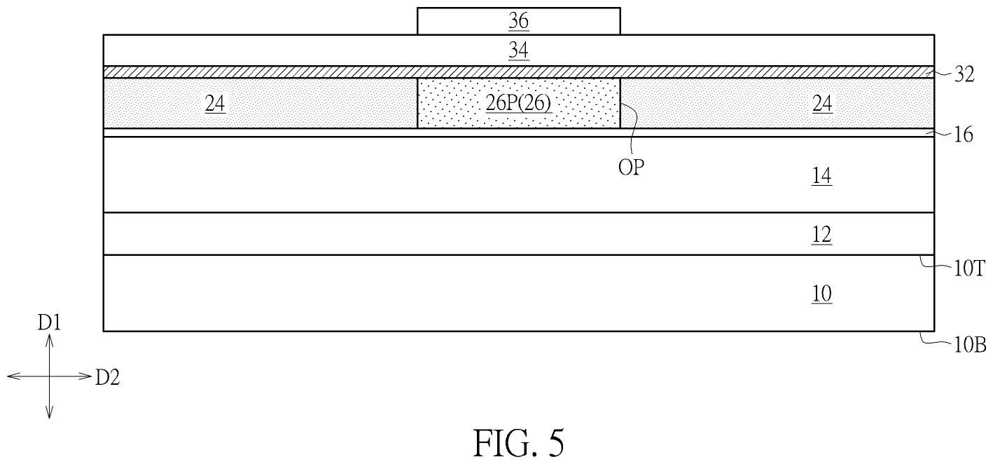

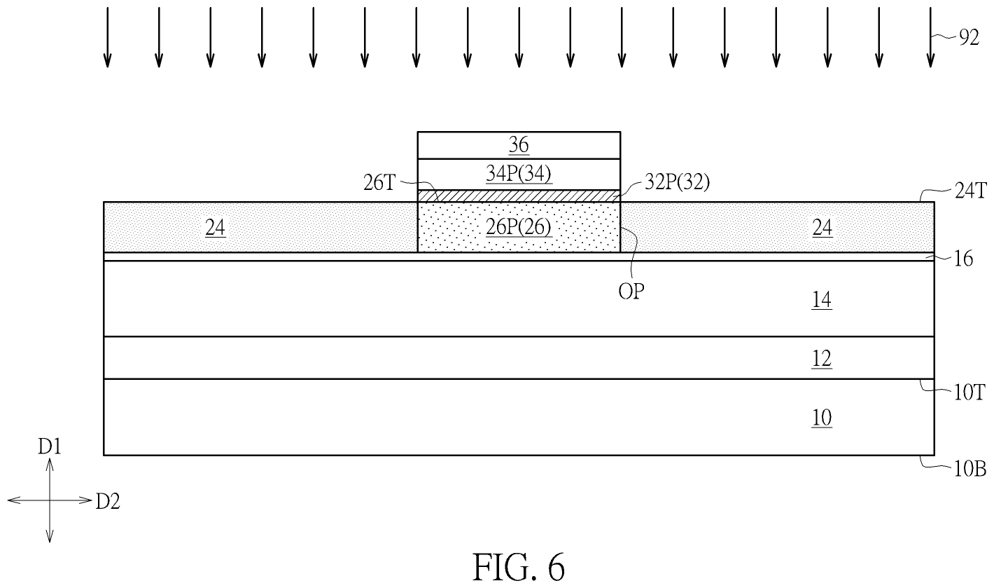

As shown in FIGS. 4-7, a patterned barrier layer 32P′ is formed on the p-type doped III-V compound material 26P. In some embodiments, a method of forming the patterned barrier layer 32P′ may include but is not limited to the following steps. After the planarization process 91, as shown in FIG. 5, a barrier layer 32 may be formed on the p-type doped III-V compound material 26P and the protection layer 24, a mask layer 34 may be formed on the barrier layer 32, and a patterned photoresist layer 36 may be formed on the mask layer 34. The barrier layer 32 may include titanium, titanium nitride, tantalum, tantalum nitride, or other suitable electrically conductive barrier materials. The mask layer 34 may include silicon oxide, silicon nitride, or other mask materials with the desired etching selectivity. Subsequently, as shown in FIG. 6, a first etching process may be performed, and the mask layer 34 may be etched to be a patterned mask layer 34P by the first etching process. In some embodiments, an etching process 92 using the patterned photoresist layer 36 as an etching mask may be performed, and the mask layer 34 may be etched to be the patterned mask layer 34P by the etching process 92. After the patterned mask layer 34P is formed, the barrier layer 32 may be etched to be a patterned barrier layer 32P by the etching process 92. Therefore, a portion of the etching process 92 (such as a first etching step) may be regarded as the first etching process described above. Another portion of the etching process 92 (such as a second etching step) may be regarded as another etching process using the patterned photoresist layer 36 and the patterned mask layer 34P as an etching mask, the barrier layer 32 may be etched to be the patterned barrier layer 32P by this etching process, and the barrier layer 32 formed on the protection layer 24 may be completely removed by this etching process, but not limited thereto. The etching process 92 may include an anisotropic etching process, such as an anisotropic dry etching process or other suitable etching approaches, and the process condition of the first etching step may be identical to or different from that of the second etching step in the etching process 92 based on some design considerations. Additionally, when the process condition (such as the reactive gases, but not limited thereto) of the first etching step is similar to that of the second etching step in the etching process 92, the material composition of the mask layer 34 may be different from the material composition of the protection layer 24 preferably for reducing the etching damage to the protection layer 24 in the etching process 92. In other words, when the material composition of the mask layer 34 is identical to or similar to that of the protection layer 24, the process condition of the second etching step in the etching process 92 may be modified for reducing the etching damage to the protection layer 24.

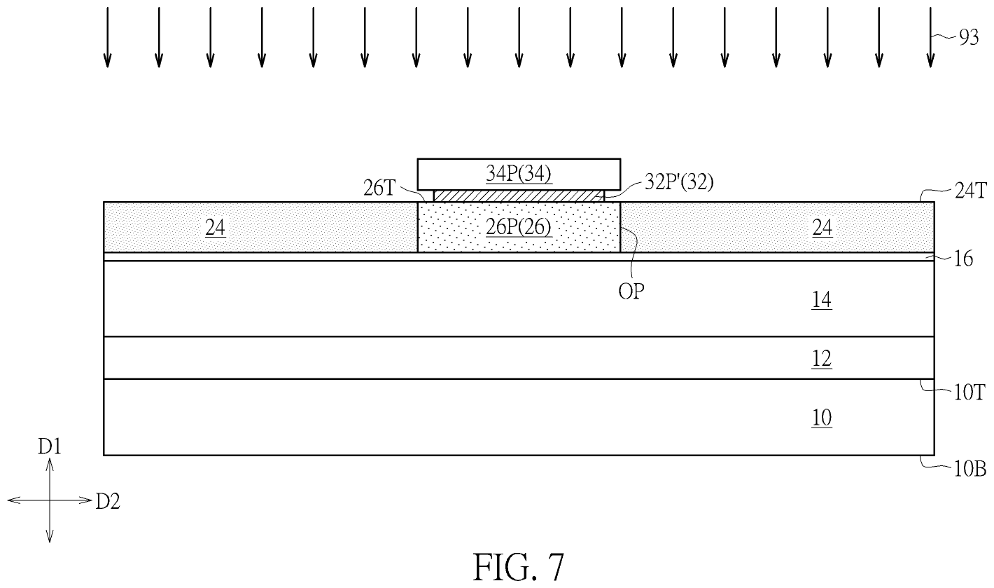

As shown in FIG. 6 and FIG. 7, after the etching process 92, an etching process 93 using the patterned mask layer 34P as an etching mask may be performed, and the barrier layer 32 (i.e. the patterned barrier layer 32P) may be further etched to be the patterned barrier layer 32P′ by the etching process 93. In some embodiments, the etching process 93 may include an isotropic etching process, such as an isotropic wet etching process or other suitable etching approaches. In addition, after the etching process 92 and before the etching process 93, the patterned photoresist layer 36 may be removed, the barrier layer 32 may be located between the patterned mask layer 34P and the p-type doped III-V compound material 26P in the direction D1 (such as being sandwiched between the patterned mask layer 34P and the p-type doped III-V compound material 26P in the direction D1), and the sidewall of the barrier layer 32 located between the patterned mask layer 34P and the p-type doped III-V compound material 26P may be partially removed by the etching process 93. The etching process 93 may be regarded as a lateral etching process, but not limited thereto. A contact area between the patterned barrier layer 32P′ and the p-type doped III-V compound material 26P in the direction D1 may be less than the total area of the top surface 26T of the p-type doped III-V compound material 26P by the lateral etching process for keeping the sidewall of the patterned barrier layer 32P′ from being aligned with the side edge of the p-type doped III-V compound material 26P. The leakage current path formed along the sidewall of the patterned barrier layer 32P′ and the side edge of the p-type doped III-V compound material 26P aligned with each other and the influence on the operation performance of the semiconductor device may be avoided accordingly.

However, in some embodiments, the contact area between the patterned barrier layer 32P and the p-type doped III-V compound material 26P may be greater than or equal to the area of the top surface 26T of the p-type doped III-V compound material 26P when the etching process 92 described above is performed without performing the etching process 93. In other words, a projection area of the patterned barrier layer 32P in the direction D1 may be greater than or equal to a projection area of the p-type doped III-V compound material 26P in the direction D1, and the top surface 26T of the p-type doped III-V compound material 26P may be covered by the patterned barrier layer 32P without being exposed. Relatively, after the etching process 93 described above, the projection area of the patterned barrier layer 32P′ in the direction D1 may be smaller than the projection area of the p-type doped III-V compound material 26P in the direction D1, and a part of the top surface 26T of the p-type doped III-V compound material 26P may not be covered by the patterned barrier layer 32P′ and may be exposed accordingly. Additionally, it is worth noting that, during the step of forming the patterned barrier layer 32P or the patterned barrier layer 32P′, the III-V compound barrier layer 16 may be covered by the protection layer 24 and the p-type doped III-V compound material 26P for reducing the etching damage to the III-V compound barrier layer 16 and/or the III-V compound semiconductor layer 14 in the etching process 92 and/or the etching process 93. The electrical performance of the semiconductor device may be improved accordingly. For example, the purposes of increasing the concentration of two-dimensional electron gas (2DEG), enhancing the drain current (Ids) of the semiconductor device, and/or lowering the leakage current of the semiconductor device may be achieved, but not limited thereto.

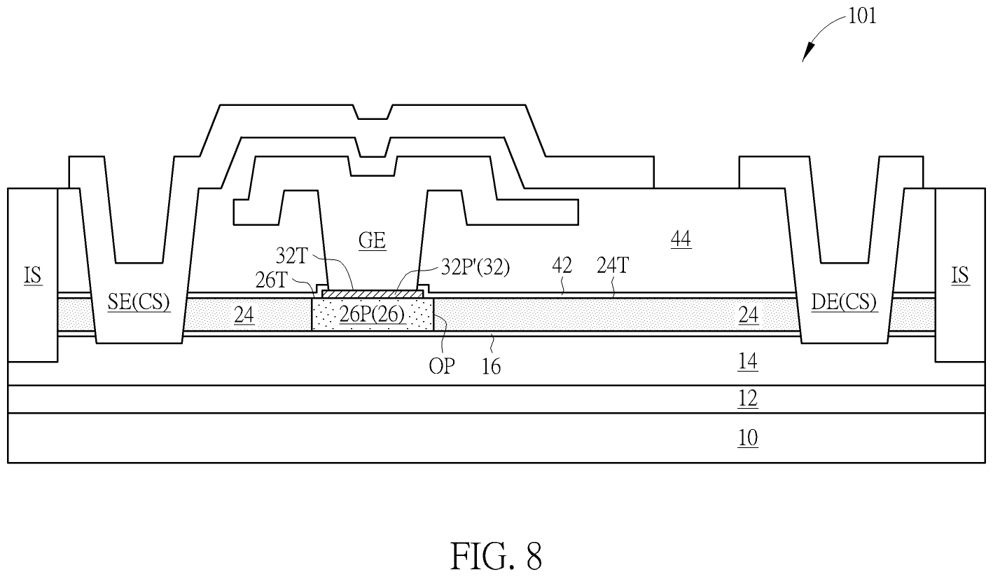

As shown in FIG. 7 and FIG. 8, after the step of forming the patterned barrier layer 32P′, the patterned mask layer 34P may be removed, and a dielectric layer 42, a dielectric layer 44, an isolation structure IS, a gate electrode GE, and a contact structure CS may be formed. The dielectric layer 42 may include an oxide dielectric material (such as aluminum oxide), a nitride dielectric material, or other suitable dielectric materials or insulation materials, and the dielectric layer 42 may be formed on the patterned barrier layer 32P′, the p-type doped III-V compound material 26P, and the protection layer 24. In some embodiments, the contact area between the patterned barrier layer 32P′ and the p-type doped III-V compound material 26P may be less than the area of the top surface 26T of the p-type doped III-V compound material 26P, and the dielectric layer 42 may directly contact the top surface 32T and the sidewall of the patterned barrier layer 32P′, the top surface 26T of the p-type doped III-V compound material 26P, and the top surface 24T of the protection layer 24, but not limited thereto. The dielectric layer 44 may be formed on the dielectric layer 42, and the dielectric layer 44 may include multiple layers of dielectric materials, such as tetraethoxy silane (TEOS), silicon oxide, silicon nitride, or other suitable dielectric materials. The isolation structure IS may penetrate through the dielectric layer 42, the dielectric layer 44, the protection layer 24, the III-V compound barrier layer 16, and a part of the III-V compound semiconductor layer 14 in the direction D1 for providing isolation effect between mesa structures. The isolation structure IS may include a single layer or multiple layers of insulation materials.

The gate electrode GE may be formed in the dielectric layer 42 and the dielectric layer 44 and formed on the patterned barrier layer 32P′. The gate electrode GE may be electrically connected with the p-type doped III-V compound material 26P via the patterned barrier layer 32P′. The contact structure CS may penetrate through the dielectric layer 42, the dielectric layer 44, the protection layer 24, the III-V compound barrier layer 16, and a part of the III-V compound semiconductor layer 14 in the direction D1 for being electrically connected with the III-V compound semiconductor layer 14. In some embodiments, a plurality of the contact structures CS may be formed, one of the contact structures CS may be regarded as a source electrode SE in a transistor structure, and another one of the contact structures CS may be regarded as a drain electrode DE in the transistor structure, but not limited thereto. The gate electrode GE and the contact structures CS may include a barrier layer (not illustrated) and a metal layer (not illustrated) disposed on the barrier layer, but not limited thereto. In some embodiments, the gate electrode GE and the contact structure CS may further include another barrier layer disposed on the metal layer described above. The barrier layer described above may include titanium, titanium nitride, tantalum, tantalum nitride, or other suitable barrier materials, and the metal layer described above may include tungsten, copper, aluminum, titanium aluminum alloy, aluminum copper alloy, or other suitable metallic materials.

The semiconductor device 101 illustrated in FIG. 8 may be formed by the manufacturing method described above. The semiconductor device 101 includes the III-V compound semiconductor layer 14, the III-V compound barrier layer 16, the protection layer 24, the opening OP, the p-type doped III-V compound material 26P, and the patterned barrier layer 32P′. The III-V compound barrier layer 16 is disposed on the III-V compound semiconductor layer 14. The protection layer 24 is disposed on the III-V compound barrier layer 16. The opening OP penetrates through the protection layer 24 in the direction D1. The p-type doped III-V compound material 26P is disposed in the opening OP. The patterned barrier layer 32P′ is disposed on the p-type doped III-V compound material 26P. The contact area between the patterned barrier layer 32P′ and the p-type doped III-V compound material 26P is less than the area of the top surface 26T of the p-type doped III-V compound material 26P.

In some embodiments, the top surface 26T of the p-type doped III-V compound material 26P and the top surface 24T of the protection layer 24 may be substantially coplanar, but not limited thereto. In addition, the semiconductor device 101 may further include the substrate 10, the buffer layer 12, the dielectric layer 42, the dielectric layer 44, the isolation structure IS, the gate electrode GE, and the contact structures CS described above. The III-V compound semiconductor layer 14 is disposed on the substrate 10, and the buffer layer 12 is disposed be between the substrate 10 and the III-V compound semiconductor layer 14. The dielectric layer 42 is disposed on the patterned barrier layer 32P′, the p-type doped III-V compound material 26P, and the protection layer 24, and the dielectric layer 44 is disposed on the dielectric layer 42. The gate electrode GE is disposed on the patterned barrier layer 32P′, and the gate electrode GE is electrically connected with the p-type doped III-V compound material 26P via the patterned barrier layer 32P′. The contact structure CS penetrates through the dielectric layer 44, the dielectric layer 42, the protection layer 24, the III-V compound barrier layer 16, and a portion of the III-V compound semiconductor layer 14 in the direction D1, and the contact structure CS is electrically connected with the III-V compound semiconductor layer 14.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

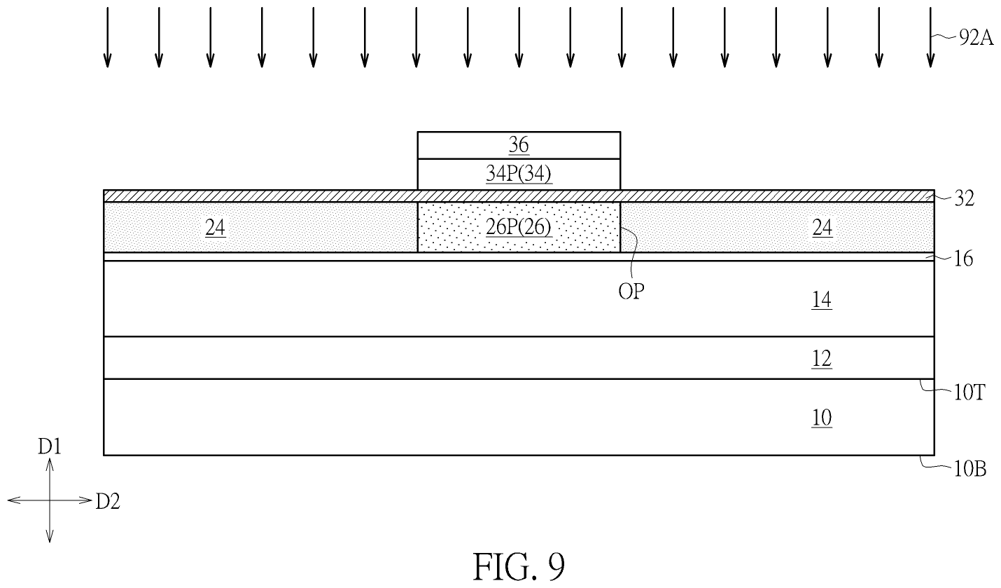

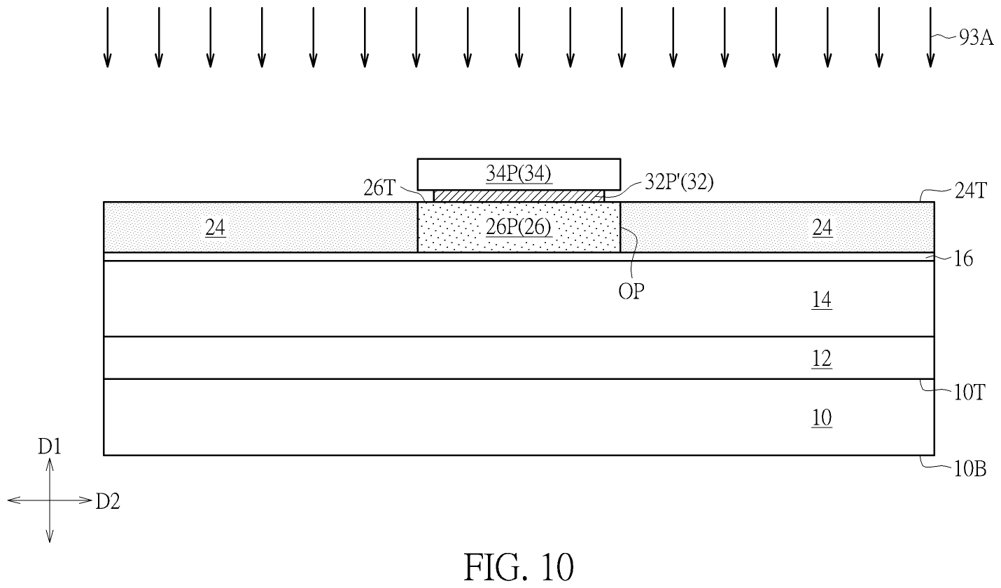

Please refer to FIG. 5, FIG. 9, and FIG. 10. FIG. 9 and FIG. 10 are schematic drawings illustrating a manufacturing method of a semiconductor device according to a second embodiment of the present invention, and FIG. 10 is a schematic drawing in a step subsequent to FIG. 9. In some embodiments, FIG. 9 may be regarded as a schematic drawing in a step subsequent to FIG. 5, but not limited thereto. As shown in FIG. 5 and FIG. 9, an etching process 92A using the patterned photoresist layer 36 as an etching mask may be performed, and the mask layer 34 may be etched to the patterned mask layer 34P by the etching process 92A. In some embodiments, the etching process 92A may have relatively high etching selectivity between the material of the mask layer 34 and the material of the barrier layer 32, the barrier layer 32 may be less likely to be etched by the etching process 92A, and the barrier layer 32 formed on the protection layer 24 is not completely removed by the etching process 92A. In other words, after the etching process 92A, the protection layer 24 may be covered by the barrier layer 32 still. Therefore, the etching process 92A may be regarded as the first etching process described above, and the etching process 92A may include an anisotropic etching process, such as an anisotropic dry etching process or other suitable etching approaches, but not limited thereto.

Subsequently, as shown in FIG. 9 and FIG. 10, an etching process 93A may be performed after the etching process 92A. In some embodiments, the patterned photoresist layer 36 may be removed after the etching process 92A and before the etching process 93A. The etching process 93A may be regarded as a second etching process using the patterned mask layer 34P as an etching mask, and the barrier layer 32 may be etched to be the patterned barrier layer 32P′ by the etching process 93A, but not limited thereto. In some embodiments, the etching process 93A may include an isotropic etching process, such as an isotropic wet etching process or other suitable etching approaches. The barrier layer 32 formed on the protection layer 24 may be completely removed by the etching process 93A, and the barrier layer 32 located between the patterned mask layer 34P and the p-type doped III-V compound material 26P in the direction D1 may be partially removed by the etching process 93A concurrently. Therefore, the contact area between the patterned barrier layer 32P′ and the p-type doped III-V compound material 26P may be less than the area of the top surface 26T of the p-type doped III-V compound material 26P after the etching process 93A. In other words, the projection area of the patterned barrier layer 32P′ in the direction D1 may be smaller than the projection area of the p-type doped III-V compound material 26P in the direction D1, and a portion of the top surface 26T of the p-type doped III-V compound material 26P may be exposed without being covered by the patterned barrier layer 32P′. In the process of forming the patterned barrier layer 32P′, the III-V compound barrier layer 16 may be covered by the protection layer 24 and the p-type doped III-V compound material 26P for reducing the negative influence of the etching process 93A on the III-V compound barrier layer 16 and/or the III-V compound semiconductor layer 14, and the electrical performance of the semiconductor device may be improved accordingly.

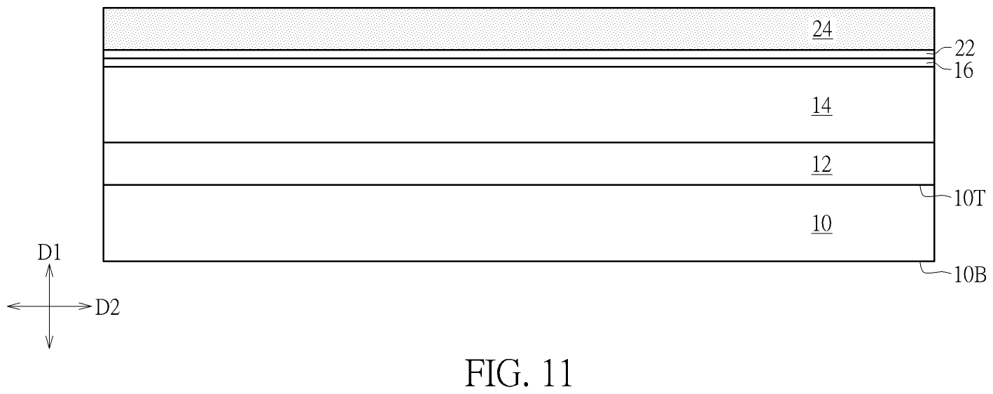

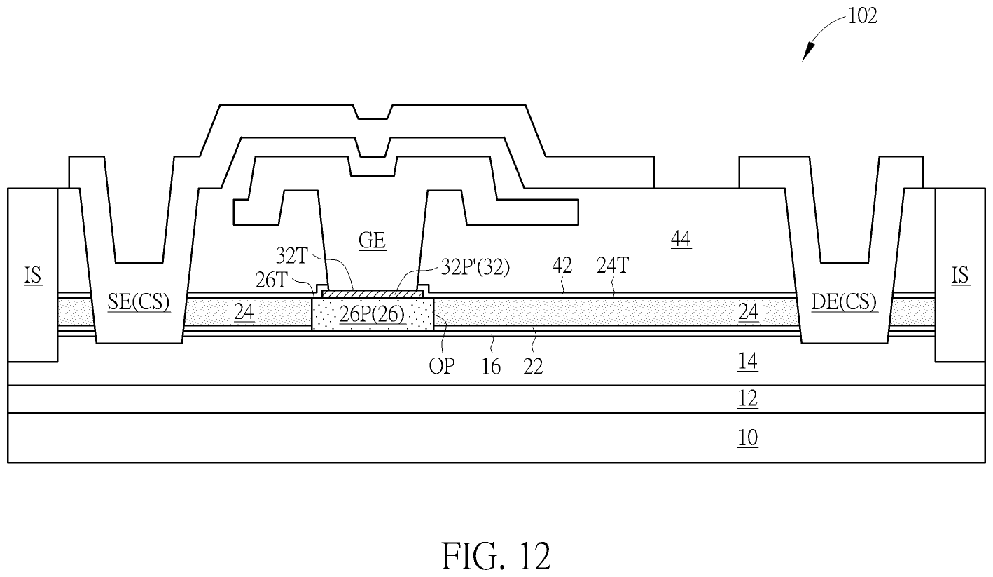

Please refer to FIG. 11 and FIG. 12. FIG. 11 and FIG. 12 are schematic drawings illustrating a manufacturing method of a semiconductor device 102 according to a third embodiment of the present invention, and FIG. 12 is a schematic drawing in a step subsequent to FIG. 11. As shown in FIG. 11, before the step of forming the protection layer 24, a dielectric layer 22 may be formed on the III-V compound barrier layer 16, and the protection layer 24 may be formed on the dielectric layer 22. The dielectric layer 22 may include an oxide dielectric material (such as aluminum oxide), a nitride dielectric material, or other suitable dielectric materials or insulation materials. As shown in FIG. 12, the semiconductor device 102 may be formed by manufacturing steps similar to those in the first embodiment described above. The difference between the semiconductor device in this embodiment and that in the first embodiment described above is that the semiconductor device 102 may further include the dielectric layer 22 disposed between the III-V compound barrier layer 16 and the protection layer 24, the opening OP may penetrate through the protection layer 24 and the dielectric layer 22 in the direction D1, and the contact structure CS may penetrate through the dielectric layer 42, the protection layer 24, the dielectric layer 22, and the III-V compound barrier layer 16 in the direction D1. In some embodiments, the material composition of the dielectric layer 22 may be different from the material composition of the protection layer 24, and the thickness of the dielectric layer 22 may be less than the thickness of the protection layer 24. Therefore, in the etching process for forming the opening OP, the etching damage to the III-V compound barrier layer 16 and/or the III-V compound semiconductor layer 14 when the relatively thick protection layer 24 has to be etched may be avoided by the disposition of the dielectric layer 22, but not limited thereto.

To summarize the above descriptions, in the semiconductor device and the manufacturing method thereof according to the present invention, the p-type doped III-V compound material may be formed in the opening penetrating through the protection layer. During the step of forming the p-type doped III-V compound material, the amount of the dopants diffused from the p-type doped III-V compound layer into the III-V compound barrier layer and/or the III-V compound semiconductor layer may be reduced by covering most of the III-V compound barrier layer with the protection layer, and the leakage current of the semiconductor device may be reduced accordingly. Additionally, during the step of forming the patterned barrier layer, the III-V compound barrier layer may be covered by the protection layer and the p-type doped III-V compound material for reducing the etching damage to the III-V compound barrier layer and/or the III-V compound semiconductor layer in the related etching processes. The electrical performance of the semiconductor device may be improved accordingly. For example, the drain current (Ids) of the semiconductor device may be enhanced because the concentration of two-dimensional electron gas (2DEG) is increased according, but not limited thereto.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor device, comprising:
forming a III-V compound barrier layer on a III-V compound semiconductor layer;
forming a protection layer on the III-V compound barrier layer,
forming an opening penetrating through the protection layer in a vertical direction and exposing a part of the III-V compound barrier layer;
forming a p-type doped III-V compound material in the opening; and
forming a patterned barrier layer on the p-type doped III-V compound material, wherein a contact area between the patterned barrier layer and the p-type doped III-V compound material is less than an area of a top surface of the p-type doped III-V compound material.

2. The manufacturing method of the semiconductor device according to claim 1, wherein a method of forming the p-type doped III-V compound material comprises:
forming a p-type doped III-V compound layer, wherein a portion of the p-type doped III-V compound layer is formed in the opening, and another portion of the p-type doped III-V compound layer is formed outside the opening and formed on the protection layer; and
performing a planarization process to the p-type doped III-V compound layer for removing the p-type doped III-V compound layer formed outside the opening, wherein the p-type doped III-V compound layer remains in the opening after the planarization process becomes the p-type doped III-V compound material.

3. The manufacturing method of the semiconductor device according to claim 2, wherein the top surface of the p-type doped III-V compound material and a top surface of the protection layer are coplanar after the planarization process.

4. The manufacturing method of the semiconductor device according to claim 1, wherein a method of forming the patterned barrier layer comprises:
forming a barrier layer on the p-type doped III-V compound material and the protection layer;
forming a mask layer on the barrier layer;
performing a first etching process, wherein the mask layer is etched to be a patterned mask layer by the first etching process; and
performing a second etching process using the patterned mask layer as an etching mask, wherein the barrier layer is etched to be the patterned barrier layer by the second etching process.

5. The manufacturing method of the semiconductor device according to claim 4, wherein the second etching process comprises an isotropic etching process.

6. The manufacturing method of the semiconductor device according to claim 4, wherein the barrier layer formed on the protection layer is removed by the first etching process, and a portion of the barrier layer is located between the patterned mask layer and the p-type doped III-V compound material and is partially removed by the second etching process.

7. The manufacturing method of the semiconductor device according to claim 4, wherein the barrier layer formed on the protection layer is removed by the second etching process.

8. The manufacturing method of the semiconductor device according to claim 4, wherein the patterned mask layer is removed after the patterned barrier layer is formed.

9. The manufacturing method of the semiconductor device according to claim 1, further comprising:
forming a first dielectric layer on the III-V compound barrier layer before the step of forming the protection layer, wherein the protection layer is formed on the first dielectric layer, and the opening further penetrates through the first dielectric layer in the vertical direction.

10. The manufacturing method of the semiconductor device according to claim 1, further comprising:
forming a second dielectric layer on the patterned barrier layer, the p-type doped III-V compound material, and the protection layer.

11. The manufacturing method of the semiconductor device according to claim 10, wherein the second dielectric layer directly contacts a top surface of the patterned barrier layer, the top surface of the p-type doped III-V compound material, and a top surface of the protection layer.

12. The manufacturing method of the semiconductor device according to claim 1, further comprising:
forming a gate electrode on the patterned barrier layer, wherein the gate electrode is electrically connected to the p-type doped III-V compound material via the patterned barrier layer.

13. The manufacturing method of the semiconductor device according to claim 1, further comprising:
forming a contact structure penetrating through the protection layer in the vertical direction, wherein the contact structure is electrically connected to the III-V compound semiconductor layer.

14. A semiconductor device, comprising:
a III-V compound semiconductor layer;
a III-V compound barrier layer disposed on the III-V compound semiconductor layer;
a protection layer disposed on the III-V compound barrier layer;
an opening penetrating through the protection layer in a vertical direction;
a p-type doped III-V compound material disposed in the opening; and
a patterned barrier layer disposed on the p-type doped III-V compound material, wherein a contact area between the patterned barrier layer and the p-type doped III-V compound material is less than an area of a top surface of the p-type doped III-V compound material.

15. The semiconductor device according to claim 14, wherein the top surface of the p-type doped III-V compound material and a top surface of the protection layer are coplanar.

16. The semiconductor device according to claim 14, further comprising:
a first dielectric layer disposed between the III-V compound barrier layer and the protection layer, wherein the opening further penetrates through the first dielectric layer in the vertical direction.

17. The semiconductor device according to claim 14, further comprising:
a second dielectric layer disposed on the patterned barrier layer, the p-type doped III-V compound material, and the protection layer.

18. The semiconductor device according to claim 17, wherein the second dielectric layer directly contacts a top surface of the patterned barrier layer, the top surface of the p-type doped III-V compound material, and a top surface of the protection layer.

19. The semiconductor device according to claim 14, further comprising:
a gate electrode disposed on the patterned barrier layer, wherein the gate electrode is electrically connected to the p-type doped III-V compound material via the patterned barrier layer.

20. The semiconductor device according to claim 14, further comprising:
a contact structure penetrating through the protection layer in the vertical direction and electrically connected to the III-V compound semiconductor layer.
